(19) United States
(12) Patent Application Publication
(10) Pub. No.: US 2013/0188328 A1
(43) Pub. Date: Jul. 25, 2013

(54) QUASI-ELECTRIC SHORT WALL

(71) Applicant: RAYTHEON COMPANY, Waltham, MA (US)

(72) Inventors: Shahrokh HASHEMI-YEGANEH, Rancho Palos Verdes, CA (US); Gary P. SCHUSTER, Larwill, IN (US); Gordon A. YAMAMOTO, Culver City, CA (US)

(73) Assignee: RAYTHEON COMPANY, Waltham, MA (US)

(21) Appl. No.: 13/743,828

(22) Filed: Jan. 17, 2013

Related U.S. Application Data
(60) Provisional application No. 61/590,536, filed on Jan. 25, 2012.

(51) Int. Cl. H05K 9/00; H01P 3/00; H01P 11/00

(52) U.S. Cl. CPC H05K 9/0049; H01P 11/00; H01P 3/00
USPC 361/818; 29/592.1; 333/12; 174/377

(57) ABSTRACT

Provided is an assembly and process for isolating internal regions of an electromagnetic cavity from interfering electromagnetic radiation. The assembly includes a first portion defining a first electrically conducting broad wall and an elongated, electrically conducting isolating wall, coupled to and extending away from the first broad wall. The assembly also includes a second portion defining a second electrically conducting broad wall and an elongated, electrically conducting trough defined therein. The trough is sized to accept at least a portion of the isolating wall. The first and second portions are adapted for assembly in a facing arrangement in which the isolating wall is aligned with the trough. When assembled, a tip portion of the isolating wall extends to a uniform depth within the trough, such that the isolating wall-trough combination substantially rejects a transfer of electromagnetic energy across the isolating wall over at least a predetermined range of wavelengths.

### RELATED APPLICATIONS

The present application claims priority to U.S. Provisional Patent Application No. 61/590,536, filed Jan. 25, 2012, which is incorporated in its entirety herein by reference.

### GOVERNMENT RIGHTS

This invention was made with Government support via Contract No. W56HZV-05-C-0724. The Government may have certain rights in this invention.

### TECHNICAL FIELD

Various embodiments are described herein relating generally to the field of waveguides and the like, and more particularly to waveguides and the like with features providing isolation.

### BACKGROUND

Electrical isolation is measure of electrical separation from other metallic structures or other factors of the environment. For a multi-port system or device, isolation between ports can be determined as a measure of current or voltage at one port resulting from a current or voltage applied at another port. For high frequency circuits and applications, isolation performance is subject to interaction of electromagnetic fields.

It is desirable in many applications to achieve some minimum level of isolation. For example, an antenna feed that connects to both a transmitter and a receiver to the same antenna would generally require substantial isolation between the transmit and receive ports of the antenna feed to prevent interference or even damage. In other applications, isolation may be required to avoid interference or contamination between dual polarized signals or sum and difference signals obtained for a common antenna.

Electrical isolation is often achieved, and particularly at high frequency operation, through some form of shielding. For example, an electrically conducting boundary, such as a screen or wall can be provided to shield regions separated by the wall. Generally, such treatment requires that an electrically conducting boundary presents a short circuit to any impinging electric fields. Such short circuits can be obtained using intimate, non-breaking interconnections of electrically conducting surfaces. Such interconnections can be obtained, for example, by machining or casting as a single work piece, or through welding, bonding, soldering, compression fit, and the like.

Assembly of enclosed chambers, such as waveguides may require internal shields or screens, for example, to isolate different ports. Such applications requiring internal shielding present some unique challenges. For example, a hollow rectangular waveguide requiring isolation between both ends (ports) can be obtained by inserting a planar conducting wall along an axis of the waveguide. The conducting wall would be arranged blocking the waveguide aperture, with intimate and unbroken electrical contacts along the edges of the isolating wall and the upper and lower broad walls of the waveguide. Intimate contact to the short walls of a rectangular waveguide may not be as critical, as the electric fields are essentially zero at the short walls due to boundary conditions of the waveguide geometry.

Construction of such a device might include separable waveguide sections (e.g., half-sections) that can be disassembled to expose the interior region. As such, the isolating wall can be connected to at least one half-section before assembly through any suitable means. Connection to the other half-section, however, would have to occur during or after mating of the different waveguide sections. Access to the interior would be at least partially blocked by the waveguide, thereby inhibiting such techniques as soldering, welding. Use of a compression type joint would generally require closely spaced fasteners in the vicinity of the shielding wall. Such fasteners might interfere with other aspects of the device, such spacing between slots or elements of an aperture antenna array.

Hence there is a need for improved methods and devices to overcome one or more of the technical problems noted above.

### SUMMARY

Described herein are embodiments of systems and techniques for isolating regions of an electromagnetic chamber, such as a waveguide, or antenna. For example, such isolation can be obtained using an electrically conducting isolating wall attached to and in electrical communication, for example in electrical contact with a separable portion of the chamber. The isolating wall is insertable within an electrically conducting trough or choke of another portion of the chamber, without physical or electrical interconnection of the isolating wall to the other portion of the chamber. When assembled, the two portions of the chamber and the isolating wall operate as if the isolating wall were attached and in electrical contact with both portions of the chamber (e.g., both broad walls of a rectangular waveguide). Beneficially, manufacture and assembly of isolated chambers is greatly simplified by avoiding problems associated with internal welds, solders, or bonding and blind mating of the isolation wall that would otherwise be necessary.

In one aspect, at least one embodiment described herein provides an electromagnetic shield assembly. The shield assembly includes a first electrically conducting wall extending along a longitudinal axis and a second electrically conducting wall extending between base and tip portions. The second wall is attached along its base portion to the first wall forming a line of intersection perpendicular to the longitudinal axis. The tip portion of the second wall extends away from the first wall. The assembly also includes a third electrically conducting wall extending along a longitudinal axis and having an electrically conducting trough. The trough defines an elongated aperture in a surface of the third wall, such that the elongated aperture extends along a direction perpendicular to the longitudinal axis. The trough is configured to accept therein at least the tip portion of the second wall when the first and third walls are arranged in facing opposition and separated by a predetermined separation distance. The tip portion of the second wall and the trough are adapted to maintain physical separation therebetween when so arranged. Such an arrangement of the tip portion of the second wall within the trough is adapted to present a low-impedance, shunt load on either side of the second wall to electromagnetic fields disposed between the first and third walls.

In some embodiments, the first and third walls are broad walls of a rectangular waveguide and the second wall is adapted to extend across substantially the entire opening of the rectangular waveguide.

In some embodiments, at least one of the first, second and third walls are formed in an electrically conducting material.

In some embodiments, at least one of the first, second and third walls include a dielectric material with an electrically conductive coating. The dielectric material may include a moldable material, such as a thermoplastic material.

In some embodiments, at least one of the first and third walls includes at least one aperture arranged for transfer of electromagnetic energy between an exterior region and a region between the first and third walls.

In some embodiments, the arrangement of the tip portion of the second wall within the trough is adapted to provide at least 20 dB isolation within a predetermined operational bandwidth.

In some embodiments, the arrangement of the tip portion of the second wall within the trough is adapted to provide to each portion of the opposing first and third walls, a respective reflection coefficient having a magnitude of about 1 and a phase of about +/−180 degrees within a predetermined operational bandwidth.

In some embodiments, the second wall is integrally formed with the first wall.

In some embodiments, the electromagnetic shield assembly further includes a dielectric material adapted to fill, at least partially, the void between the first and third walls are arranged in facing opposition and separated by a predetermined separation distance.

In some embodiments, the electromagnetic shield assembly isolates first and second electronic circuits positionable between the first and third walls when arranged in facing opposition and separated by a predetermined separation distance, wherein arrangement of the tip portion of the second wall within the trough is adapted to substantially isolate each of the first and second electronic circuit with respect to each other within a predetermined operational bandwidth.

In another aspect, at least one embodiment described herein relates to a process for electromagnetically isolating adjacent regions. The process includes bringing first and second electrically conducting walls into facing arrangement, wherein the first wall includes an elongated, electrically conducting fin joined along a base portion to the first wall and a tip portion extending away from the first wall. The second wall includes an electrically conducting elongated trough defining an elongated aperture along a surface of the second wall. The fin and trough are each arranged perpendicular to a central axis. The tip portion of the elongated fin is aligned with respect to the elongated aperture. A uniform portion of the elongated fin is inserted through the elongated aperture, such that the tip portion extends to a predetermined depth within the elongated trough, while also maintaining electrical isolation between the fin and the trough. A relative position of the first and second walls is maintained by securing the first and second walls with respect to each other to also maintain the fin position within the trough. Such an arrangement of the fin within the trough presents a low-impedance, shunt load on either side of the fin, to electromagnetic fields disposed between the first and second walls

In some embodiments, securing the relative position of the first and second walls includes using a fastener.

In some embodiments, the process further includes inserting a dielectric material to at least one side of the fin, in a region defined between the first and second walls.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A illustrates an exploded perspective view of an embodiment of an aperture antenna with an isolating wall.

FIG. 1B illustrates a longitudinal cross section of the aperture antenna illustrated in FIG. 1A.

FIG. 2 illustrates an exploded top perspective view of a simplified embodiment of an electromagnetic isolator.

FIG. 3 illustrates a bottom perspective view of an upper portion of the electromagnetic isolator illustrated in FIG. 2

FIGS. 4A and 4B respectively illustrate an exploded top perspective view and top perspective view of another embodiment of an electromagnetic isolator.

FIGS. 5A and 5B respectively illustrate an exploded top perspective view and top perspective view of an embodiment of an electromagnetically isolated rectangular waveguide.

FIGS. 6A and 6B respectively illustrate an exploded top perspective view and top perspective view of another embodiment of an electromagnetically isolated rectangular waveguide.

FIGS. 7A and 7B respectively illustrate an exploded top perspective view and top perspective view of an embodiment of an electromagnetically isolated aperture antenna.

FIG. 8 illustrates cross sectional view of one portion of an electromagnetic isolating assembly.

FIG. 9 illustrates cross sectional view of another portion of an electromagnetic isolating assembly.

FIG. 10 illustrates cross sectional view of one portion of another embodiment of an electromagnetic isolating assembly.

FIG. 11 illustrates cross sectional view of another portion of another embodiment of an electromagnetic isolating assembly.

FIG. 12 illustrates a longitudinal cross section of a portion of an embodiment of a waveguide bisected by an open-ended isolating wall.

FIG. 13 illustrates an exploded perspective view of an embodiment of a shielded enclosure internally sectioned by an open-ended isolating wall.

### DETAILED DESCRIPTION

A description of embodiments of systems and processes for isolating regions of an electromagnetic chamber follows. More particularly, such isolation is obtained using an electrically conducting isolating wall attached to and in electrical communication (i.e., electrical contact) with a separable portion of the chamber. The isolating wall is insertable within an electrically conducting trough or choke of another portion of the chamber without physical or electrical interconnection of the isolating wall to the other portion of the chamber. When assembled, the two portions of the chamber and the isolating wall operate as if the isolating wall were attached and in electrical contact with both portions of the chamber. Consequently, manufacture and assembly of isolated chambers is greatly simplified by avoiding problems associated with internal welds, solders, or bonding and blind mating of the isolation wall that would otherwise be necessary.

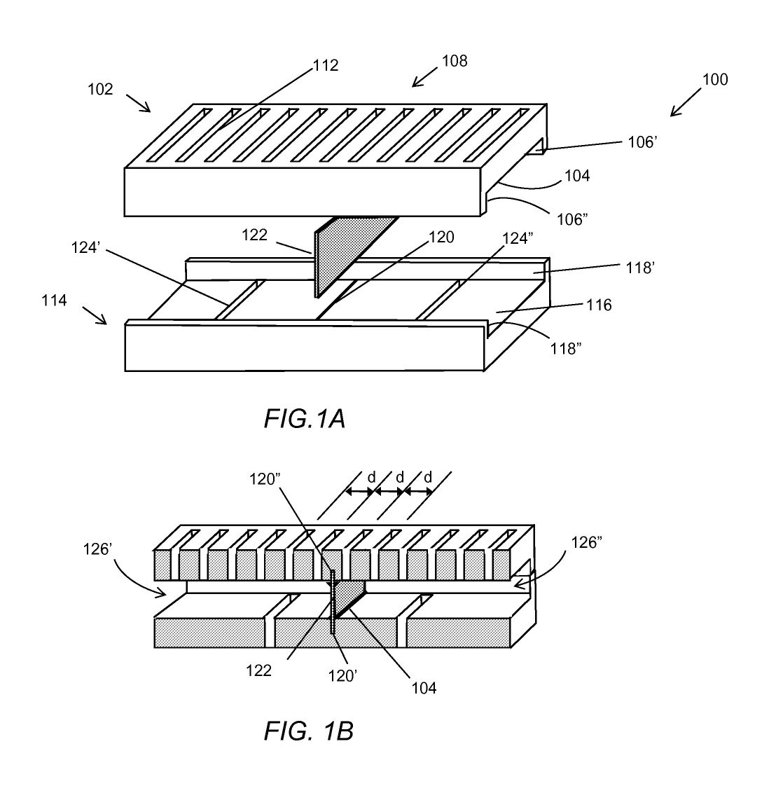

FIG. 1A illustrates an exploded perspective view of an embodiment of an isolated, dual-port aperture antenna assembly 100. The antenna assembly 100 includes an upper housing 102 defining an upper broad wall 104 extending along a longitudinal axis and bounded on either side by a semi-short wall 106′, 106″ (generally 106). The upper housing 102 includes an array of slot apertures 108 open to the upper broad wall 104. In the illustrative example, each of the slot apertures 112 is substantially identical in dimension and orientation, being aligned orthogonal to the longitudinal axis.

The antenna assembly 100 also includes a lower housing 114 defining a lower broad wall 116 extending along the longitudinal axis and bounded on either side by semi-short walls 118′, 118″ (generally 118). The upper and lower housings 102, 114 are joinable together along edges of their respective semi-short walls 106, 118 to define a rectangular waveguide cavity 126, shown in the cross section of FIG. 1B. The lower housing 114 includes a lower mounting slot 120′ bisecting the lower broad wall 116 into left and right portions. The upper broad wall 104 includes a similar, upper mounting slot 120″. The antenna assembly 100 includes an isolating wall 122 dimensioned to fit within each of the upper and lower mounting slots 120′, 120″. The isolating wall 122 is also dimensioned to extend across the entire cross section of the rectangular waveguide cavity 122.

Each of the upper and lower broad walls 104, 116 and the upper and lower semi-short walls 106, 118 has an electrically conducting surface conductive to the propagation of electromagnetic (e.g., microwave, millimeter wave and the like) radiation. Likewise, the isolating wall 122 also presents electrically conducting surfaces on either side. To ensure electromagnetic isolation between the left and right waveguide sections when assembled, a substantially complete electrical connectivity is required at least along the isolation wall 122 intersection with the upper and lower broad walls 104, 116. Such connections can be accomplished by a weld, soldering, an interference fit, an electrically conductive glue, epoxy, or paste, and combinations of any of these. Alternatively or in addition, mechanical fasteners (not shown), such as screws or rivets can be provided in the vicinity of the isolating wall 122 to join the upper and lower housings 102, 114, thereby ensuring a secure and complete joint along the edges of the isolating wall 122 joining the upper and lower broad walls 104, 116.

Also shown are left and right feed ports 124′, 124″ (generally 124). Electromagnetic energy can be coupled between the respective one of the left and right waveguide cavities 126′, 126″ and an external source through the feed ports 124. In a transmit mode of operation, electromagnetic energy is introduced into the left and right waveguide cavities 126′, 126″ through the respective feed port 124. Electromagnetic energy from each respective waveguide cavity 126′, 126″ is coupled to a far field by way of the aperture array 108. Isolation between the left and right waveguide cavities 126′, 126″ allows respective halves of the aperture array to operate substantially independently. For example, in some embodiments, sum and difference signals are managed through respective feed ports 124, without interference therebetween.

It is apparent that assembly of the various components of the antenna assembly 100 (e.g., the upper and lower housings 102, 114 and the isolating wall 122) pose serious challenges considering that precise positioning of the isolating wall 122 is necessary as the upper and lower housings 102, 114 are brought together. This effectively results in a blind mate of the isolating wall 122 into one of the upper and lower mounting slots 120′, 120″. Without proper alignment, there remains the possibility of damage (e.g., bending, cracking, crimping of one or more of the components). Additionally, forming a complete peripheral electrical contact through any suitable techniques, such as those described herein, would be extremely challenging performed within the confines of the waveguide cavity 126, when joined. Any compromise to proper placement and electrical contact jeopardizes isolation performance.

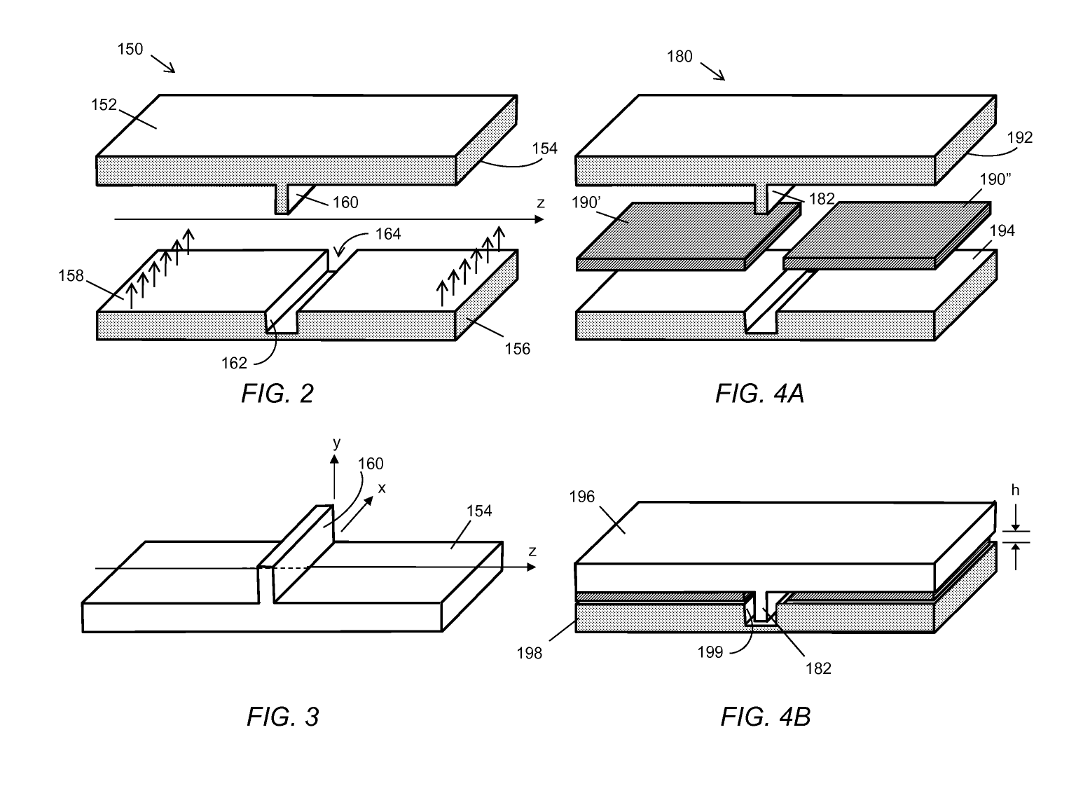

FIG. 2 illustrates an exploded top perspective view of an embodiment of an electromagnetic isolator. A parallel plate waveguide assembly 150 includes an upper portion 152 defining a first broad wall 154 and a lower portion 156, defining a second broad wall 158, each extending in a direction parallel to a longitudinal axis z. The parallel plate waveguide is defined by the first and second broad walls 154, 158 when they are brought into a facing arrangement, separated by a predetermined height. Example electric field lines are shown extending from the second broad wall 158. Such fields would terminate on the first broad wall 154 when separated by the predetermined height (e.g., greater than or equal to one half of the longest anticipated wavelength of operation to avoid blocking by waveguide-below-cutoff phenomenon).

An isolating wall 160 protrudes away from first broad wall 154 in a direction towards the second, facing broad wall 158. The isolating wall 160 has a base portion adjoining the first broad wall 154 along a direction orthogonal to the longitudinal axis. Referring to FIG. 3, which illustrates an inner side of the upper portion 152, the isolating wall 160 is defined in the y-x plane, which is orthogonal to the elongated z axis. A line representing intersection of the isolating wall 160 with the first broad wall 154 is aligned with the x axis, again orthogonal to the longitudinal z axis.

Referring again to FIG. 2, the second broad wall 158 defines an elongated trough 162. The trough 162 terminates in an aperture 164 defined in the second broad wall 158. The trough 162 is also aligned perpendicular with the longitudinal axis and positioned to accept at least a tip portion of the isolating wall 160 when the plates are overlapped in facing arrangement and separated by a predetermined height. The trough 162 is dimensioned to accept the tip portion of the isolating wall 160 without the possibility of physical and/or electrical contact.

Once again, the first and second broad walls 154, 158, the isolating wall 160 and the walls of the trough 162 are electrically conducting surfaces. Preferably, the isolating wall 160 is physically joined and in electrical contact with the first broad wall 154. For example, the isolating wall 160 can be formed integrally with the upper portion (e.g., milled or cast from the same block of metal (e.g., aluminum). Likewise, the walls of the trough 162 are also electrically conducting

FIG. 4A illustrates an exploded top perspective view of another embodiment of parallel plate waveguide assembly 180 having an electromagnetic isolating wall 182. In this embodiment dielectric material 190′, 190″ is provided between the first and second broad walls 192, 194. FIG. 4B illustrates upper and lower portions 196, 198 assembled, with first and second broad walls 192, 194 overlapping and spaced apart by a predetermined height h. A tip portion of the isolating wall 182 is shown inserted within the trough 199.

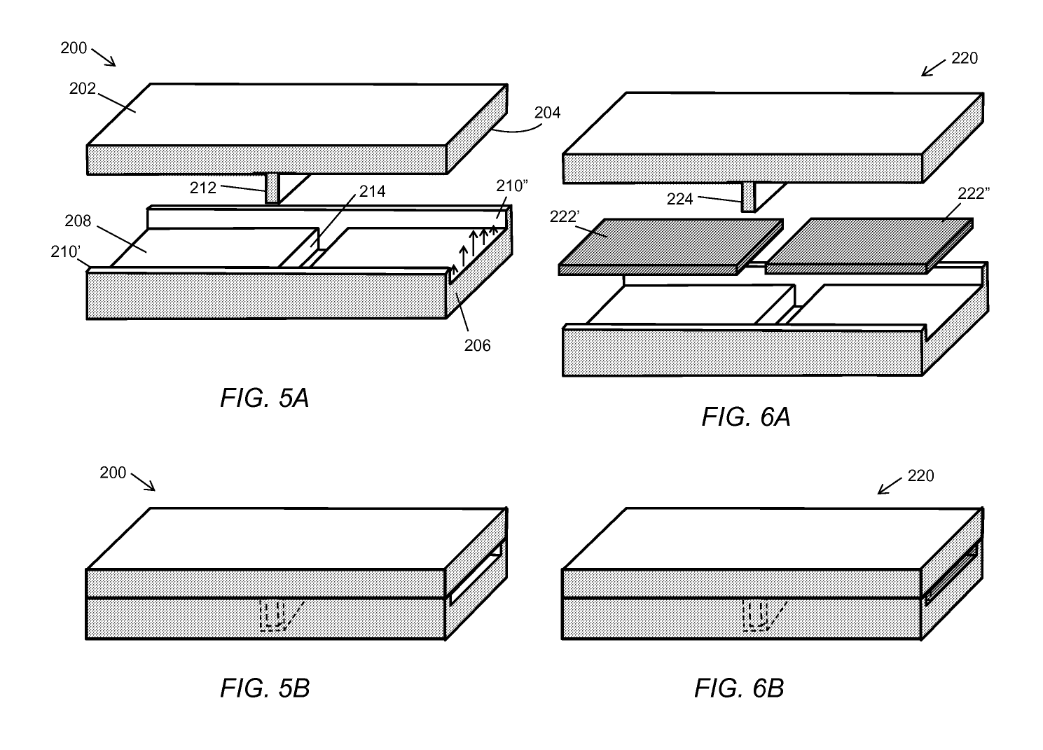

FIG. 5A illustrates an exploded top perspective view of another embodiment of an electromagnetic isolator. A rectangular waveguide assembly 200 includes an upper portion 202 defining a first broad wall 204 and a lower portion 206, defining a second broad wall 208, each extending in a direction parallel to a longitudinal axis z. The lower portion 206 includes short walls 210′, 210″ along outer edges of the second broad wall 208 and extending away from the second broad wall 208.

The rectangular waveguide is defined by the first and second broad walls 204, 208 and the left and right short walls 210′, 210″ when the two portions 202, 206 are brought into a facing arrangement. In the illustrative embodiment, upper edges of the short walls 210′, 210″ abut the first broad wall 204 when assembled, resulting in separation of the first and second broad walls 202, 206 by a predetermined height h (i.e., the height of the short walls 210′, 210″). Other embodiments having short walls extending from the upper portion 202 instead of the lower portion 206, or with semi-short walls extending from each of the upper and lower portions 202, 206 are contemplated.

Example electric field lines are shown extending from the second broad wall 208. Such electric field lines would terminate on the first broad wall 204 when separated by the predetermined height (e.g., greater than or equal to one half of the longest anticipated wavelength of operation to avoid blocking by waveguide-below-cutoff phenomenon). Similar to the parallel plate waveguide assembly described above, an isolating wall 212 extends perpendicularly away from the first broad wall 204. The isolating wall 212 being elongated along a direction orthogonal to a longitudinal axis. A trough 214 is defined in the second broad wall 208, and dimensioned to accept at least a tip portion of the isolating wall 212 when assembled. Disposition of the tip portion of the isolating wall within the trough 214 is illustrated in the assembled rectangular waveguide assembly of FIG. 5B.

FIGS. 6A and 6B illustrate another embodiment of a rectangular waveguide assembly 220. The waveguide assembly 220 includes essentially the same waveguide components as shown above, with the addition of dielectric material 216′, 216″. The dielectric material, when a solid, can be sized to fit within the rectangular cavity of the rectangular waveguide, on either side of the isolating wall 224.

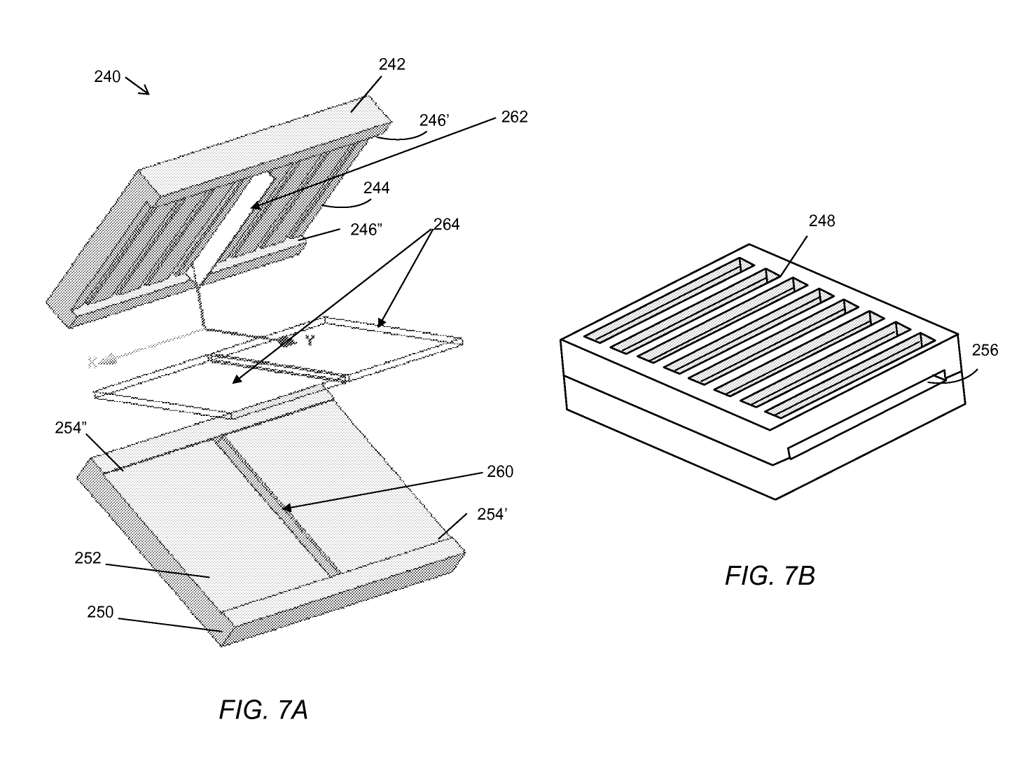

FIG. 7A illustrates an exploded top perspective view an embodiment of an electromagnetically isolated aperture antenna assembly 240, shown assembled in a top perspective view of FIG. 7B. The antenna assembly 240 includes an upper housing 242 defining a first broad wall 244 extending along a longitudinal axis and bounded on either side by a semi-short wall 246′, 246″ (generally 246). The upper housing includes an array of slot apertures 248 open to the first broad wall 244.

The antenna assembly 240 also includes a lower housing 250 defining a second broad wall 252 extending along the longitudinal axis and bounded on either side by semi-short walls 254′, 254″ (generally 254). The upper and lower housings 242, 250 are joinable together along edges of their respective semi-short walls 246, 254 to define a rectangular waveguide cavity 256. The lower housing 250 includes a trough 260 bisecting the second broad wall 252 into left and right portions. An isolating wall 262 extends from the upper broad wall 244, bisecting it into left and right portions. The isolating wall 262 is positioned to fit with an opening of the trough 260 when the upper and lower housings are assembled. Also shown are sections of dielectric material 264 dimensioned to fit within the rectangular waveguide, along either edge of the isolating wall 262, when assembled.

Advantageously, the isolating wall 262 and trough 260 combination is configured to provide similar isolation performance to the isolation wall 122 of FIGS. 1A and 1B, without having to attach the isolating wall 262 to the lower housing 250. This greatly simplifies assembly of the upper and lower housings, in that it eliminates the blind mate and all related problems, as well as eliminating any need to provide an electrical interconnection of the isolating wall 262 to the lower housing 250. Isolation performance is ensured by proper positioning and dimensioning of the isolation wall 262 and the trough 260 as will be described in more detail below. Accordingly, the upper and lower housings 242, 250 need only be joined along abutting edges of the semi-short walls 246, 254.

FIG. 8 illustrates cross sectional view of an upper housing 302 of an electromagnetic isolating assembly. The upper housing 302 defines a first electrically conducting broad wall 304. An electrically conducting isolating wall 306 is attached to the upper housing 302 by inserting a base portion of the isolating wall 306 into a narrow slot 308 defined in the first broad wall 304. The isolating wall 306 is physically secured to the upper housing 302 and in electrical contact with the first broad wall 304. A tip portion of the isolating wall 306 extends away from the first broad wall 304 by a distance d₁ (e.g., 0.15 inches). Also visible is a portion of the upper semi-short wall 310.

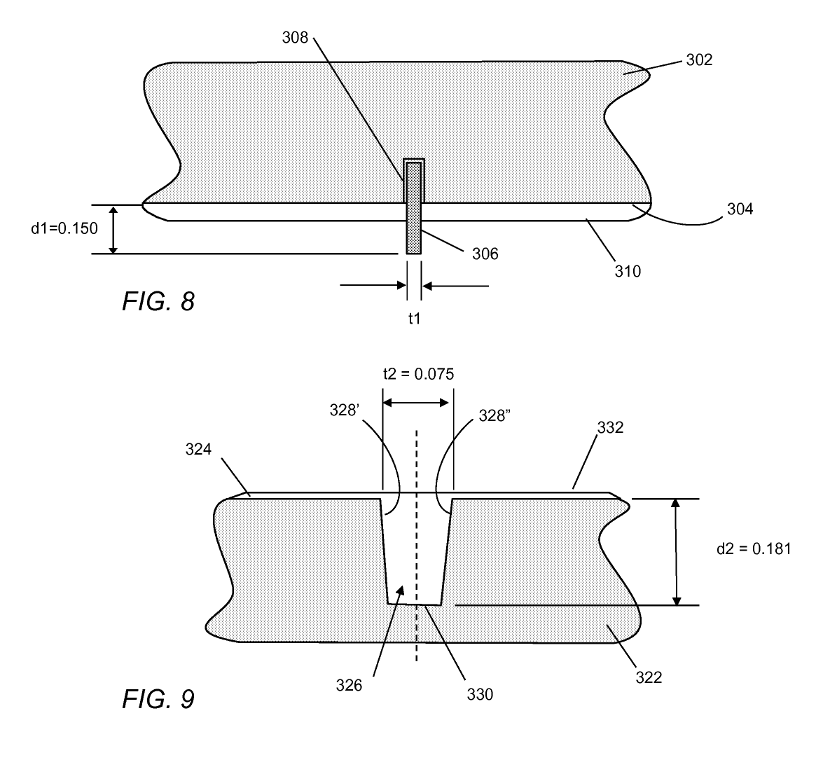

FIG. 9 illustrates cross sectional view of a lower housing 322 of an electromagnetic isolating assembly. The lower housing 322 defines a second electrically conducting broad wall 324. An electrically conducting trough 326 is defined in the lower housing 322. The trough 326 includes left and right side walls 328′, 328″ (generally 328) and a bottom wall 330. In some embodiments the side walls are parallel to each other and perpendicular to the second broad wall. In other embodiments, at least one of the side walls 328 are tapered, for example being wider at the aperture and narrower at the bottom of the trough 326. An open end of the trough 326 defines an elongated aperture in the second broad wall 324. Also visible is a portion of the lower semi-short wall 332. The aperture opening has a width t₂ (e.g., 0.075 inches), measured along the longitudinal axis and extends to a depth d₂ measured from the second broad wall 324 to the bottom wall 330 of the trough 326 (e.g., 0.181 inches). The isolating wall itself has a nominal thickness t₁. The isolating wall can be relatively thin, as shown, for example being formed from a thin strip of metal. In some embodiments, the wall can be thicker, without affecting performance as long as the aperture is widened accordingly. In the example embodiment, each of the upper and lower housings and the isolating wall 306 are formed from electrically conducting material, such as metals, including metal alloys.

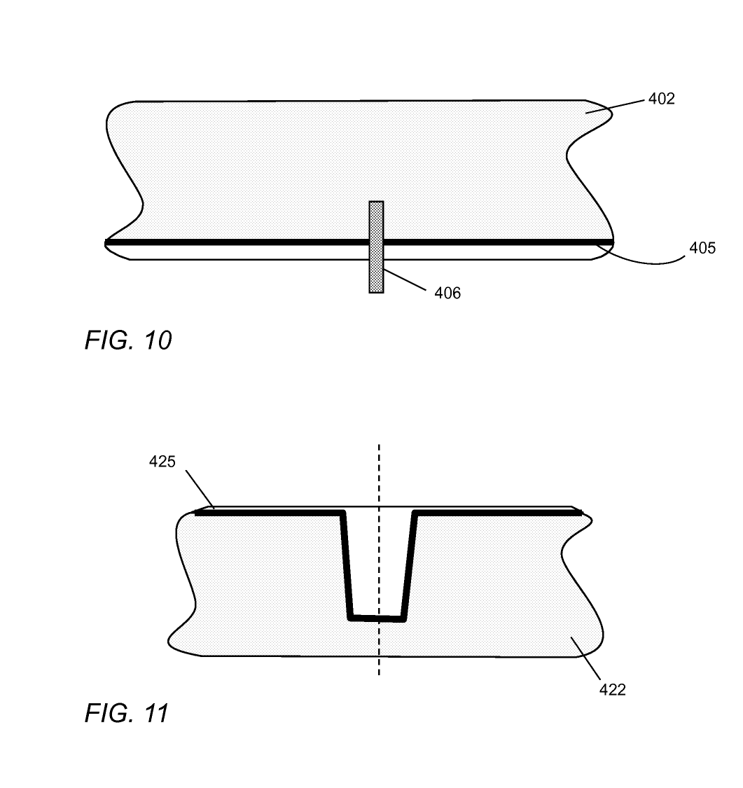

FIG. 10 illustrates cross sectional view of an upper housing 402 of another embodiment of an electromagnetic isolating assembly. The upper housing 402 is similar in all respects to the upper housing 322 described above (FIG. 8), with the exception of an electrically conductive layer 405 extending along the surface of a first broad wall 404. In this embodiment, an isolating wall 406 is a thin electrically conducting strip of material. It is envisioned that the isolating wall may also be fashioned to be encased by the electrically conductive layer.

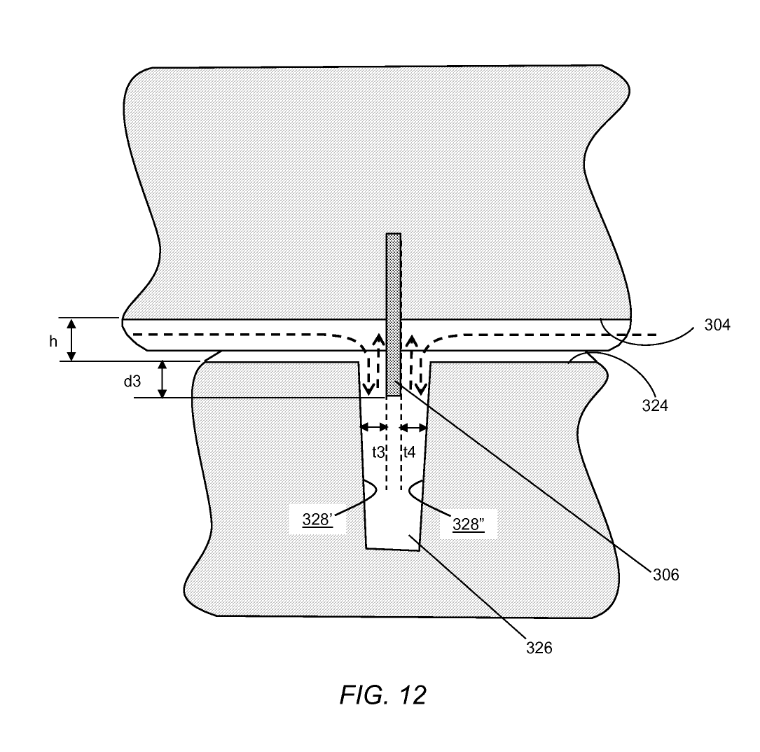

Likewise, FIG. 11 illustrates cross sectional view of a lower housing 422 of an electromagnetic isolating assembly. The lower housing 422 is similar in all respects to the lower housing 322 described above (FIG. 9), with the exception of an electrically conductive layer 425 extending along the surface of a second broad wall 424.

Advantageously, with inclusion of electrically conductive layers 405, 425, the underlying upper and lower housings 402, 422 can be fashioned from electrically conducting or insulating materials. In some embodiments, the various components, such as the upper and lower housings 402, 422 are fashioned from a thermoplastic material, for example, by an injection molding process. Each housing 402, 422 is then coated with respective electrically conducting layers 405, 425 by standard coating processes generally known those skilled in the art. Such processes include but are not limited to, painting (e.g., roll, brush, spray, dip), spraying, chemical vapor deposition, physical vapor deposition, chemical and electrochemical techniques, such as electroplating and sputtering.

FIG. 12 illustrates a longitudinal cross section of the upper and lower housings of FIG. 8 and FIG. 9 in an assembled configuration. As illustrated, the first and second broad walls 304, 324 are parallel and separated by a distance h. The isolating wall 306 is substantially centered within the trough 326, with a tip portion extending to a depth d₃ measured from the second broad wall 324. The isolating wall 306 is separated from each side wall 328′, 328″ by a distance t₃ and t₄. In some embodiments, t₃=t₄. In some embodiments, t₃≠t₄. The depth d₃ is approximately one-quarter wavelength of operation.

An open circuit formed at the tip region of the isolating wall 306 when viewed at the quarter wavelength distance from the tip region to the second broad wall 324, translates the open circuit to a short circuit. The trough 326 alone would have represented a series inductance or choke to electromagnetic waves propagating within the waveguide cavity. Addition of the electrically conducting fin, however, to a depth that is one quarter wavelength results in a shunt load, having a value of a short circuit (i.e., 0 Ohms). Thus, the reflection coefficient of the isolating wall 306 viewed from either the right or left portions of the waveguide cavity, have a magnitude of substantially one and a phase of +/−180 degrees. Isolation performance between the left and right portions of the waveguide cavity can be obtained by measure of a transmission coefficient (i.e., a measure of energy transferred from one side of the isolation wall 306 to the other. Estimates suggest that isolation of at least about 20 dB or better can be obtained. In some embodiments, such isolation can be obtainable over a bandwidth of about, for example, +/−10%.

Although the technique of isolating regions of an electrically conducting cavity have been described above in relation to waveguides and antenna assemblies, it is contemplated that such approaches are applicable more generally to other structures. For example, an isolating wall attached at one edge and seated in an open trough along another edge can be used to provide isolation to closely spaced electronic circuits.

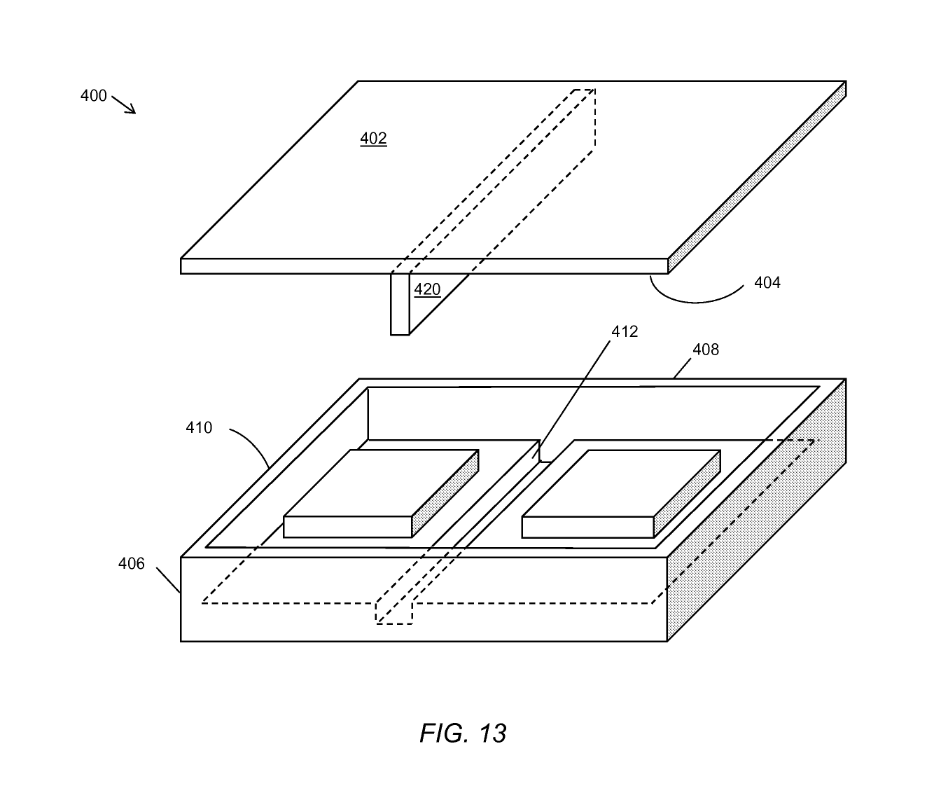

Referring next to FIG. 13, an exploded perspective view of an embodiment of a shielded enclosure assembly internally sectioned by an open-ended isolating wall is illustrated. The enclosure assembly 400 includes an upper housing 402 defining a first broad wall 404 and a lower housing 406, defining a second broad wall 408 (e.g., circuit card assembly). The lower portion also includes a perimeter wall 410 extending away from the second broad wall 408, towards the first broad wall 404. An isolating wall 420 protrudes away from first broad wall 404 in a direction towards the second, facing broad wall 408. The isolating wall 420 has a base portion adjoining the first broad wall 404.

The second broad wall 408 defines an elongated trough 412. The trough 412 is aligned to accept at least a tip portion of the isolating wall 420 when the upper and lower housings 402, 406 are overlapped in facing arrangement. In some embodiments, the upper housing 402 is dimensioned to cover an upper edge of the perimeter wall 410 in an abutting fashion. The trough 412 is dimensioned to accept the tip portion of the isolating wall 420 without the possibility of contact. The first and second broad walls 404, 408, interior surfaces of the perimeter wall 410, and the isolating wall 420 are electrically conducting. One or more of these components may be constructed from electrically conducting material, such as metals, or from dielectric materials with an electrically conducting coating.

An interior volume of the shielded enclosure assembly 400 is thus partitioned by the isolating wall 420. A first electronic circuit 421 is located on one side of the isolating wall 420 and a second electronic circuit 422 is located on the other. Should either of these circuits give rise to electromagnetic radiation within an isolation design bandwidth, such radiation will be isolated by the combination of the isolating wall 420 and trough 412. Isolation design bandwidth refers to that band or bands of energy at which the depth of the tip portion of the isolating wall 420 within the trough is an approximate multiple of quarter wavelengths. The bandwidths include those wavelengths for which isolation performance is acceptable (e.g., greater than 20 dB).

Comprise, include, and/or plural forms of each are open ended and include the listed parts and can include additional parts that are not listed. And/or is open ended and includes one or more of the listed parts and combinations of the listed parts.

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

What is claimed is:

1. An electromagnetic shield assembly comprising:
a first electrically conducting wall extending along a longitudinal axis;
a second electrically conducting wall extending between base and tip portions; the second wall attached along its base portion to the first wall forming a line of intersection perpendicular to the longitudinal axis, whereby the tip portion extends away from the first wall; and
a third electrically conducting wall extending along a longitudinal axis and having an electrically conducting trough defining an elongated aperture in the third wall, the elongated aperture extending along a direction perpendicular to the longitudinal axis,
wherein the trough is configured to accept therein at least the tip portion of the second wall when the first and third walls are arranged in facing opposition and separated by a predetermined separation distance, the tip portion of the second wall and the trough being adapted to maintain physical separation therebetween when so arranged, and
wherein such an arrangement of the tip portion of the second wall within the trough is adapted to present a low-impedance, shunt load on either side of the fin to electromagnetic fields disposed between the first and third walls.

2. The electromagnetic shield assembly of claim 1, wherein the first and third walls are broad walls of a rectangular waveguide, the second wall being adapted to extend across substantially the entire opening of the rectangular waveguide.

3. The electromagnetic shield assembly of claim 1, wherein at least one of the first, second and third walls are formed in an electrically conducting material.

4. The electromagnetic shield assembly of claim 1, wherein at least one of the first, second and third walls comprise a dielectric material with an electrically conductive coating.

5. The electromagnetic shield assembly of claim 4, wherein the dielectric material comprises a thermoplastic material.

6. The electromagnetic shield assembly of claim 1, at least one of the first and third walls comprises at least one aperture arranged for transfer of electromagnetic energy between an exterior region and a region between the first and third walls.

7. The electromagnetic shield assembly of claim 1, wherein the arrangement of the tip portion of the second wall within the trough is adapted to provide at least 20 dB isolation within a predetermined operational bandwidth.

8. The electromagnetic shield assembly of claim 1, wherein the arrangement of the tip portion of the second wall within the trough is adapted to provide to each portion of the opposing first and third walls, a respective reflection coefficient having a magnitude of about 1 and a phase of about +/−180 degrees within a predetermined operational bandwidth.

9. The electromagnetic shield assembly of claim 8, wherein the second wall is integrally formed with the first wall.

10. The electromagnetic shield assembly of claim 9, further comprising a dielectric material adapted to fill, at least partially, the void between the first and third walls are arranged in facing opposition and separated by a predetermined separation distance.

11. The electromagnetic shield assembly of claim 1, wherein the shield assembly isolates first and second electronic circuits positionable between the first and third walls when arranged in facing opposition and separated by a predetermined separation distance, wherein arrangement of the tip portion of the second wall within the trough is adapted to substantially isolate each of the first and second electronic with respect to each other within a predetermined operational bandwidth

12. A method for electromagnetically isolating adjacent regions, comprising:
bringing first and second electrically conducting walls into facing arrangement, wherein the first wall comprises an elongated, electrically conducting fin joined along a base portion to the first wall and having a tip portion extending away from the first wall, and the second wall comprises an electrically conducting elongated trough defining an elongated aperture along a surface of the second wall, the fin and trough each arranged perpendicular to a central axis;
aligning the tip portion of the elongated fin with respect to the elongated aperture;
inserting a uniform portion of the elongated fin through the elongated aperture, such that the tip portion extends to a predetermined depth within the elongated trough, while also maintaining electrical isolation between the fin and the trough; and
securing a relative position of the first and second walls with respect to each other to maintain the fin position within the trough, wherein such arrangement of the fin within the trough presents a low-impedance, shunt load on either side of the fin, to electromagnetic fields disposed between the first and second walls

13. The method of claim 12, wherein securing the relative position of the first and second walls comprises using a fastener.

14. The method of claim 12, further comprising inserting a dielectric material to at least one side of the fin, in a region defined between the first and second walls.
